(19) United States
(12) Patent Application Publication
(10) Pub. No.: US 2026/0190237 A1
(43) Pub. Date: Jul. 2, 2026

(54) MULTI-THICKNESS PRINTED CIRCUIT BOARD

(71) Applicant: SK Hynix NAND Product Solutions Corp. (dba Solidigm), Rancho Cordova, CA (US)

(72) Inventors: Kai-Uwe Schmidt, Vancouver (CA); Andrew Morning-Smith, Vancouver (CA)

(21) Appl. No.: 19/005,966

(22) Filed: Dec. 30, 2024

(51) Int. Cl. H05K 1/18; H01R 12/72; H05K 5/00

(52) U.S. Cl. CPC H05K 1/181; H01R 12/721; H05K 5/0026; H05K 2201/09009; H05K 2201/10189; H05K 2201/10545

(57) ABSTRACT

In accordance with some embodiments of the present disclosure, a printed circuit board (PCB) and a device including thereof are disclosed herein. The PCB includes a first portion of a first thickness, a second thickness portion less than the first thickness, and one or more additional portions, where each additional portion is of a thickness greater than the second thickness. The first portion of the PCB includes a first end of the PCB, and the first portion is configured to implement a connector. Each additional portion is configured to accommodate at least one electrical component, and each additional portion is at least partially surrounded by the second portion. The present disclosure also includes a solid-state drive (SSD) including a PCB and an enclosure to house the PCB, the PCB includes a first portion of a first thickness and a second portion of a second thickness less than the first thickness.

### TECHNICAL FIELD

The present disclosure is directed to printed circuit boards, devices and solid-state drives (SSDs) configured to accommodate electrical components included therein.

### SUMMARY

In accordance with the present disclosure, printed circuit boards (PCBs) and devices (e.g., SSD devices) including thereof are provided to accommodate electrical components. The PCB includes a first portion of a first thickness and a second portion of a second thickness which is less than the first thickness. In addition, the PCB may include one or more additional portions, each of which is of a thickness greater than the second thickness. The first portion includes a first end of the PCB on which a connector is implemented. The devices presented herein each include an enclosure and are configured to accommodate electrical components (e.g., memory units, memory controllers, etc.), which would otherwise not fit within the enclosure.

In some embodiments, the connector is configured to connect to a slot.

In some embodiments, each additional portion is arranged at a location on the PCB based on the locations of each electrical component accommodated by the additional portion.

In some embodiments, the PCB includes a major plane, a top side and a bottom side, each parallel to the major plane. In some embodiments, the PCB includes circuitry that includes electrical components.

In some embodiments, the electrical components include a first subset of electrical components disposed on the top side of the PCB and a second subset of electrical components disposed on the bottom side of the PCB.

In some embodiments, the connector is an Enterprise and Datacenter Standard Form Factor (EDSFF) connector.

In some embodiments, the enclosure of the device (e.g., SSD device) is one of an (a) E3.L form factor, (b) E3.S form factor, (c) E1.L form factor, or E1.S form factor.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, and/or characteristic included in at least one implementation. Thus, phrases such as “in some embodiments” appearing herein describe various embodiments and implementations, and do not necessarily all refer to the same one or more embodiment. However, they are also not necessarily mutually exclusive.

FIG. 1 shows a cross-sectional view diagram of a device;

FIG. 2 shows a cross-sectional view diagram of a device, in accordance with some embodiments of the present disclosure;

FIGS. 3A-B show diagrams of a cross-sectional view and a plan view, respectively, of another device, in accordance with some embodiments of the present disclosure; and

FIG. 4 shows a plan view diagram of another device, in accordance with some embodiments of the present disclosure.

### DETAILED DESCRIPTION

In accordance with the present disclosure, PCBs are provided for devices (e.g., solid-state drive (SSD) devices) to accommodate electrical components of different sizes (e.g., different heights). The device (e.g., SSD device) includes a PCB on which circuitry (e.g., electrical components and conductive traces) is arranged and an enclosure to house the PCB. In some embodiments, the electrical components may include (a) integrated circuits (ICs) such as a system on a chip (SoC), central processing units (CPUs), and controllers (e.g., memory controller), (b) memory components (e.g., NAND, DRAM, or any other suitable memory), and (c) passive electrical components such as capacitors, resistors, inductors, diodes, and transistors. A first end of the PCB is configured to include a connector, such as an Enterprise and Datacenter Standard Form Factor (EDSFF) connector. In some embodiments, the connector may be configured to connect to a slot on another PCB. In embodiments where the PCB is connected via the connector to the slot on the other PCB, the PCB is communicatively coupled to the other PCB.

The PCB of the device may be defined by a major plane, where the PCB includes a top side and a bottom side, each of which is parallel to the major plane. In some embodiments, a first subset of the circuitry (e.g., the electrical components and conductive traces) is disposed on the top side of the PCB and a second subset of circuitry (e.g., the electrical components and conductive traces) is disposed on the bottom side of the PCB.

The device (e.g., SSD device) includes an enclosure, which is configured to house the PCB. The enclosure may be any one of an (a) E3.L form factor, (b) E3.S form factor, (c) E1.L form factor, or (d) E1.S form factor, or any other suitable form factor to house the PCB and circuitry disposed thereon.

Although, in some embodiments, the enclosure is of a standardized form factor (e.g., any one of E3.L form factor, E3.S form factor, E1.L form factor, or E1.S form factor), the sizes (i.e., height) of electrical components 104 may vary. Some electrical components disposed on the PCB may be too large in size (i.e., too tall in height) to fit within the form factor of the enclosure. In some cases, a larger enclosure may be implemented to accommodate the large electrical components of the circuitry. However, in other cases, the form factor of the enclosure may be standardized and cannot be changed for particular implementations.

The device (e.g., SSD device) includes a first portion and a second portion of PCB. The first portion is of a first thickness and the second portion is of a second thickness which is less than (e.g., thinner) than the first thickness. The first portion may be disposed at the first end of the PCB and used to implement a connector. The first thickness of the first portion may be defined by one or more of (a) the type of connector or (b) the form factor of the enclosure.

In some embodiments, the second thickness of the second portion may be thinner than the first portion such that the electrical components which otherwise would be too large in size (i.e., too tall in height) to fit within the form factor of the enclosure. In some embodiments, the second portion of the PCB includes fewer PCB layers than the first portion. The second portion of the PCB is configured to accommodate electrical components disposed on each of the top side and bottom side of the PCB, within the enclosure. The device (e.g., SSD device) may further include an additional portion of a thickness that is greater than the second thickness. Each additional portion may be disposed on the PCB to accommodate one or more electrical components. In some embodiments, electrical components, such as light-emitting diodes (LEDs), may be raised on the additional portion to be arranged near the enclosure. In some embodiments, one additional portion may accommodate more than one electrical component. In some embodiments, the thickness of the additional portions may be defined by the size (e.g., height) of the electrical components.

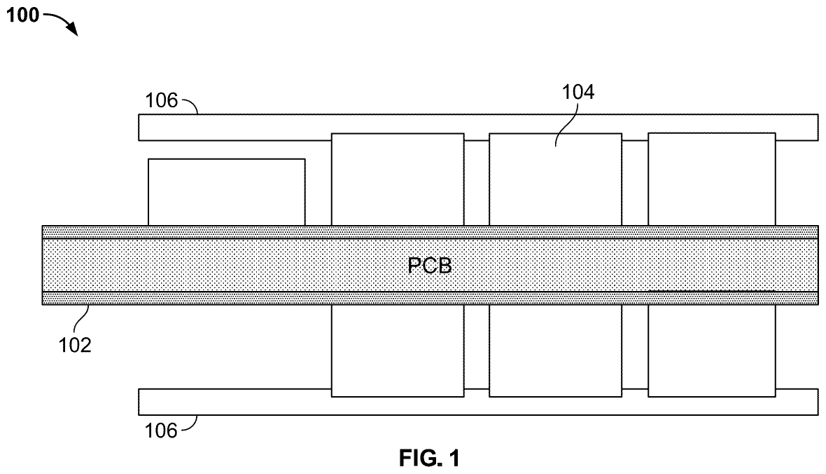

The subject matter of this disclosure is further discussed with reference to FIGS. 1-4.

FIG. 1 shows a cross-sectional view diagram of a device 100 (e.g., an SSD device). Device 100 includes PCB 102 on which circuitry (e.g., electrical components 104 and conductive traces) is arranged and enclosure 106 to house PCB 102. In some embodiments, the electrical components 104 may include (a) integrated circuits (ICs) such as a system on a chip (SoC), central processing units (CPUs), and controllers (e.g., memory controller), (b) memory components (e.g., NAND, DRAM, or any other suitable memory), and (c) passive electrical components such as capacitors, resistors, inductors, diodes, and transistors. A first end of PCB 102 is configured to include a connector (e.g., Enterprise and Datacenter Standard Form Factor (EDSFF) connector), which is not shown in FIG. 1. In some embodiments, the connector may be configured to connect to a slot on another PCB (not shown in FIG. 1). In embodiments where the PCB 102 is connected via the connector to the slot on the other PCB, the PCB 102 is communicatively coupled to the other PCB.

As shown in FIG. 1, PCB 102 of device 100 may be defined by a major plane, where the PCB 102 includes a top side and a bottom side, each of which is parallel to the major plane. In some embodiments, a first subset of circuitry (e.g., electrical components 104 and conductive traces) is disposed on the top side of PCB 102 and a second subset of circuitry (e.g., electrical components 104 and conductive traces) is disposed on the bottom side of PCB 102.

Device 100 includes enclosure 106, which is configured to house the PCB 102. Enclosure 106 may be of a form factor, including any one of an (a) E3.L form factor, (b) E3.S form factor, (c) E1.L form factor, or (d) E1.S form factor, or any other suitable form factor to house PCB 102 and electrical components 104 disposed thereon.

Although, in some embodiments, enclosure 106 is of a standardized form factor (e.g., any one of E3.L form factor, E3.S form factor, E1.L form factor, or E1.S form factor), the sizes (i.e., height) of electrical components 104 may vary. As shown in FIG. 1, some electrical components 104 disposed on PCB 102 may be too large in size (i.e., too tall in height) to fit within the form factor of enclosure 106. In some cases, a larger enclosure may be implemented to accommodate the large electrical components 104. However, in other cases, the form factor of enclosure 106 may be standardized and cannot be changed for particular implementations.

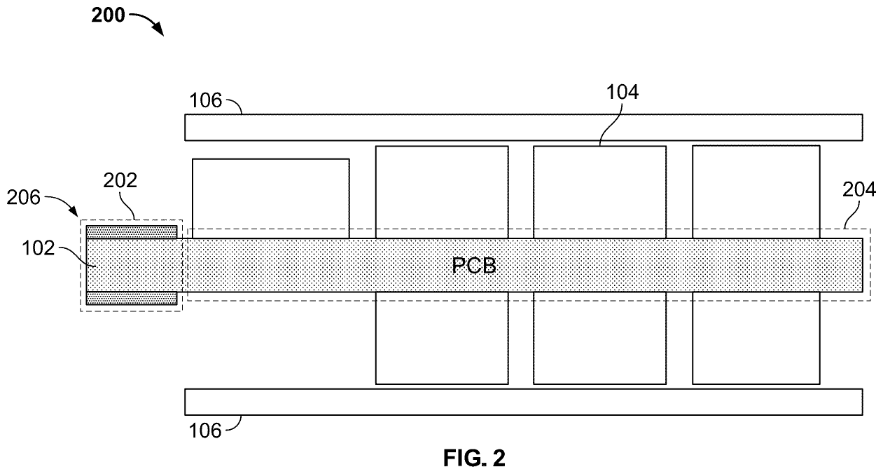

FIG. 2 shows a cross-sectional view diagram of device 200, in accordance with some embodiments of the present disclosure. Similar to device 100, device 200 includes PCB 102, electrical components 104, and enclosure 106. Device 200 further shows a first portion 202 and a second portion 204 of PCB 102. As shown in FIG. 2, the first portion 202 is of a first thickness and the second portion 204 is of a second thickness which is less than (e.g., thinner) than the first thickness. The first portion 202 may be disposed at a first end of PCB 102 and used to implement a connector 206. In some embodiments, connector 206 is an EDSFF connector. The first thickness of the first portion 202 may be a thickness defined by one or more of (a) the type of connector or (b) the form factor of enclosure 106. In some embodiments, connector 206 may be configured to connect to a corresponding slot on another PCB (not shown in FIG. 2). In embodiments where the PCB 102 is connected via connector 206 to the slot on the other PCB, the PCB 102 is communicatively coupled to the other PCB.

In some embodiments, the second thickness of second portion 204 may be thinner than first portion 202 such that electrical components 104 which otherwise would be too large in size (i.e., too tall in height) for enclosure 106. In some embodiments, the second portion 204 of PCB 102 includes fewer PCB layers than first portion 202. The second portion 204 of PCB 102 may be formed to accommodate electrical components 104 on each of the top side and bottom side of the PCB 102 within enclosure 106.

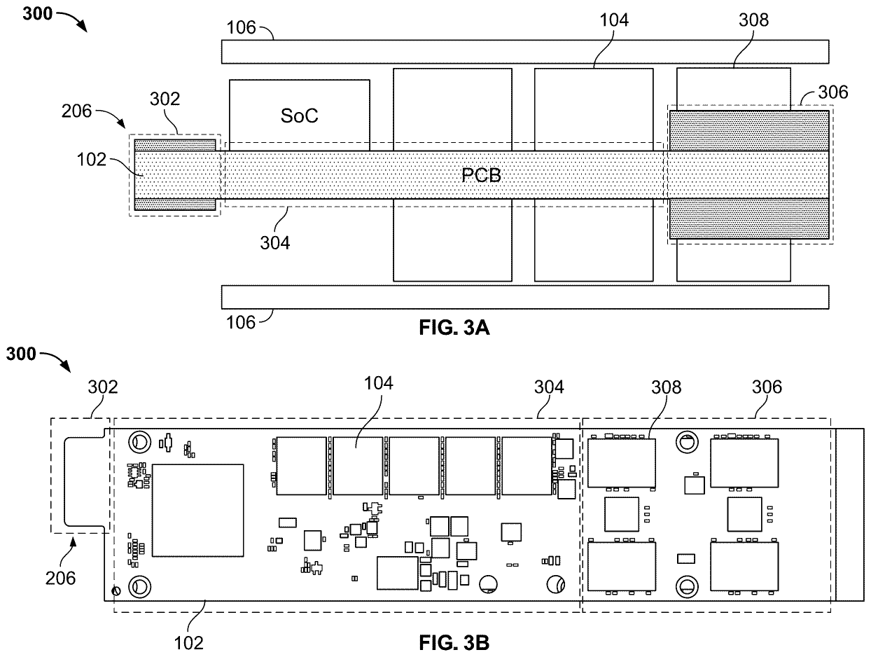

FIGS. 3A-B show diagrams of a cross-sectional view and a plan view, respectively, of another device 300, in accordance with some embodiments of the present disclosure. Similar to device 200, device 300 includes PCB 102, electrical components 104, enclosure 106, a first portion 302 disposed at the first end of PCB 102 and used to implement connector 206, and a second portion 304. Device 300 further shows an additional portion 306 of PCB 102. As shown in FIG. 3, the first portion 302 is of a first thickness, second portion 304 is of a second thickness which is less than (e.g., thinner) than the first thickness, and the additional portion 306 is of a thickness that is greater than the second thickness. Additional portion 306 may be disposed on PCB 102 to accommodate one or more electrical components 308. It will be understood that electrical components 308 may include any suitable electrical physical feature, but not necessarily a distinct component. For example, electrical components 308 may include an electrically conductive mounting hole, surface-mountable electrical component, or any suitable electrical physical feature, or any combination thereof. In some embodiments, electrical components 308, such as light-emitting diodes (LEDs), may need to be raised on the additional portion (e.g., additional portion 306) of PCB 102 to be align and arrange the electrical components 308 (e.g., LED) near the enclosure 106. For example, additional portions 306 may accommodate an LED (e.g., electrical component 308) for the LED to efficiently emit light through an opening in enclosure 106. In some embodiments, the location of electrical component 308 (e.g., an LED) is specified by an industry standard or respective form factor of PCB 102. In some embodiments, PCB 102 may include more than one additional portion 306. In some embodiments, one additional portion 306 may accommodate more than one electrical component 308. Additional portions 306 may also be disposed on PCB 102 to be in contact with enclosure 106 to improve electrostatic discharge (ESD) immunity of device 300. The first thickness of the first portion 302 may be a thickness defined by one or more of (a) the type of connector 206 or (b) the form factor of enclosure 106. In some embodiments, the second thickness of the second portion 304 may be a thickness defined by a size (e.g., height) of electrical components 104. In some embodiments, the thickness of the additional portions 306 may be defined by a size (e.g., height) of electrical components 308.

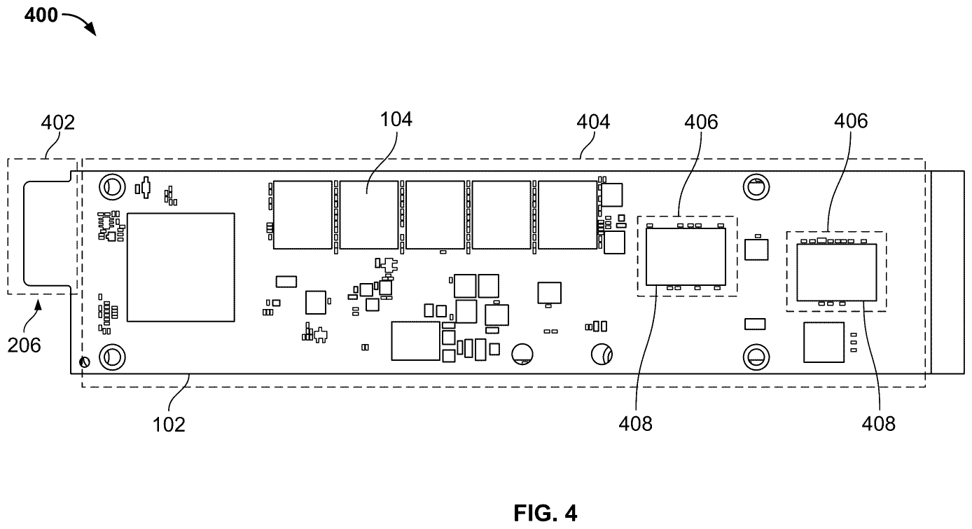

FIG. 4 shows a plan view diagram of another device 400, in accordance with some embodiments of the present disclosure. Similar to device 300, device 400 includes PCB 102, electrical components 104, enclosure 106, a first portion 402 disposed at the first end of PCB 102 and used to implement connector 206, a second portion 404, and additional portions 406 of PCB 102. As shown in FIG. 4, the first portion 402 is of a first thickness, second portion 404 is of a second thickness which is less than (e.g., thinner) than the first thickness, and the additional portion 406 is of a thickness that is greater than the second thickness. Additional portion 406 may be disposed on PCB 102 to accommodate one or more electrical components 408. In some embodiments, electrical components 408, such as light-emitting diodes (LEDs), may be raised on the additional portion (e.g., additional portion 406) of PCB 102 to be arranged near enclosure 106. In some embodiments, PCB 102 may include more than one additional portion 406. In some embodiments, one additional portion 406 may accommodate more than one electrical component 408. The first thickness of the first portion 402 may be a thickness defined by one or more of (a) the type of connector 206 or (b) the form factor of enclosure 106. In some embodiments, the second thickness of the second portion 404 may be a thickness defined by a size (e.g., height) of electrical components 104. In some embodiments, the thickness of the additional portions 406 may be defined by a size (e.g., height) of electrical components 408.

The term “end” when referring to an end of a PCB or a circuit means “distal end” unless expressly specified otherwise.

The terms “an embodiment”, “embodiment”, “embodiments”, “the embodiment”, “the embodiments”, “one or more embodiments”, “some embodiments”, and “one embodiment” mean “one or more (but not all) embodiments” unless expressly specified otherwise.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments. Further, although process steps, method steps, algorithms or the like may be described in a sequential order, such processes, methods, and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments need not include the device itself.

At least certain operations that may have been illustrated in the figures show certain events occurring in a certain order. In alternative embodiments, certain operations may be performed in a different order, modified, or removed. Moreover, steps may be added to the above-described logic and still conform to the described embodiments. Further, operations described herein may occur sequentially or certain operations may be processed in parallel. Yet further, operations may be performed by a single processing unit or by distributed processing units.

The foregoing description of various embodiments has been presented for the purposes of illustration and description. It is not intended to be exhaustive or to be limited to the precise forms disclosed. Many modifications and variations are possible in light of the above teaching.

What is claimed is:

1. A printed circuit board (PCB) comprising:
a first portion of a first thickness;
a second portion of a second thickness less than the first thickness;
one or more additional portions, each portion of which is of a thickness greater than the second thickness, wherein:
the first portion comprises a first end of the PCB, and wherein the first portion is configured to implement a connector, and
each of the one or more additional portions is configured to accommodate at least one electrical component, and wherein each of the one or more additional portions is at least partially surrounded by the second portion.

2. The PCB of claim 1, wherein the connector is configured to connect to a slot.

3. The PCB of claim 1, wherein each respective additional portion of the one or more additional portions is arranged at a location on the PCB based on a location of each of the at least one electrical component the each respective additional portion is configured to accommodate.

4. The PCB of claim 1, further comprising:
a major plane;
a top side parallel to the major plane;
a bottom side parallel to the major plane; and
circuitry that comprises a plurality of electrical components, wherein the plurality of electrical components comprises the at least one electrical component.

5. The PCB of claim 4, wherein the plurality of electrical components further comprises:
a first subset of electrical components disposed on the top side; and
a second subset of electrical components disposed on the bottom side.

6. The PCB of claim 1, wherein the connector is an Enterprise and Datacenter Standard Form Factor (EDSFF) connector.

7. A device comprising:
a printed circuit board (PCB) comprising:
a first portion of a first thickness;
a second portion of a second thickness less than the first thickness; and
one or more additional portions, each portion of which is of a thickness greater than the second thickness, wherein:
the first portion comprises a first end of the PCB, and wherein the first portion is configured to implement a connector, and
each of the one or more additional portions is configured to accommodate at least one electrical component, and wherein each of the one or more additional portions is at least partially surrounded by the second portion; and
an enclosure configured to house the PCB.

8. The device of claim 7, wherein the connector is configured to connect to a slot.

9. The device of claim 7, wherein each respective additional portion of the one or more additional portions is arranged at a location on the PCB based on a location of each of the at least one electrical component the each respective additional portion is configured to accommodate.

10. The device of claim 7, wherein the PCB further comprises:
a major plane;
a top side parallel to the major plane;
a bottom side parallel to the major plane; and
circuitry that comprises a plurality of electrical components, wherein the plurality of electrical components comprises the at least one electrical component.

11. The device of claim 10, wherein the plurality of electrical components further comprises:
a first subset of electrical components disposed on the top side; and
a second subset of electrical components disposed on the bottom side.

12. The device of claim 7, wherein the connector is an Enterprise and Datacenter Standard Form Factor (EDSFF) connector.

13. The device of claim 7, wherein the enclosure comprises thermally-conductive material.

14. The device of claim 7, wherein the enclosure is one of an: (a) E3.L form factor, (b) E3.S form factor, (c) E1.L form factor, or E1.S form factor.

15. A solid-state drive (SSD), comprising:
a printed circuit board (PCB) comprising:
a first portion of a first thickness; and
a second portion of a second thickness less than the first thickness; and
an enclosure configured to house the PCB.

16. The SSD of claim 15, wherein the first portion comprises a first end of the PCB, and the first portion is configured to implement a connector configured to connect to a slot.

17. The SSD of claim 16, wherein the connector is an Enterprise and Datacenter Standard Form Factor (EDSFF) connector.

18. The SSD of claim 15, wherein the PCB further comprises:
a major plane;
a top side parallel to the major plane;
a bottom side parallel to the major plane; and
circuitry that comprises a plurality of electrical components.

19. The SSD of claim 18, wherein the plurality of electrical components further comprises:
a first subset of electrical components disposed on the top side; and
a second subset of electrical components disposed on the bottom side.

20. The SSD of claim 15, wherein the enclosure is one of an: (a) E3.L form factor, (b) E3.S form factor, (c) E1.L form factor, or E1.S form factor.
